(19) United States
(12) Patent Application Publication
(10) Pub. No.: US 2020/0203661 A1
(43) Pub. Date: Jun. 25, 2020

(54) DISPLAY DEVICE FOR PREVENTING CORROSION OF LINE AND ELECTRONIC DEVICE INCLUDING THE SAME

(71) Applicant: Samsung Electronics Co., Ltd., Suwon-si, Gyeonggi-do (KR)

(72) Inventor: Jung-Bae BAE, Hanam-si (KR)

(21) Appl. No.: 16/645,430

(22) PCT Filed: Sep. 21, 2018
(86) PCT No.: PCT/KR2018/011238

§ 371 Date: Mar. 6, 2020

(30) Foreign Application Priority Data
Sep. 26, 2017 (KR) 10-2017-0124452

(51) Int. Cl. H01L 51/52; H01L 27/32

(52) U.S. Cl. CPC H01L 51/5256; H01L 27/323; H01L 27/3276; H01L 51/524

(57) ABSTRACT

Disclosed are various embodiments related to a display device. According to an embodiment, a display device may include: a window; a display panel configured to be disposed, at least in part, in a direction facing the window; and a cover panel configured to be disposed in a direction facing the display panel and configured to protect at least a portion of the display panel, wherein the display panel may include at least one insulating layer disposed at edges of the display panel. Various other embodiments may be possible.

### CROSS-REFERENCE TO RELATED APPLICATIONS

This application is a National Phase Entry under 35 U.S.C. § 371 of PCT International Application No. PCT/KR2018/011238, which was filed on Sep. 21, 2018, and claims priority to Korean Patent Application No. 10-2017-0124452, which was filed in the Korean Intellectual Property Office on Sep. 26, 2017, the entire contents of each of which are incorporated herein by reference.

### BACKGROUND

### 1. Field

The disclosure relates generally to display device for preventing corrosion of line and electronic device including the same.

### 2. Description of Related Art

Various types of electronic devices have been developed and popularized, as electronic technologies have advanced. For example, portable electronic devices, such as smart phones, notebook PCs, tablet PCs, and wearable devices, are spreading widely.

Displays including a touch screen panel have been widely applied to the portable electronic devices in order to widen the display area while reducing weight and thickness thereof. In particular, an Active Matrix Organic Light-Emitting Diode (AMOLED) display having an excellent optical characteristic is popular, among the displays including the touch screen panel.

### SUMMARY

The present disclosure has been made to address the above-mentioned problems and disadvantages, and to provide at least the advantages described below.

According to various embodiments, a display device may include: a window; a display panel configured to be disposed, at least in part, in a direction facing the window; and a cover panel configured to be disposed in a direction facing the display panel and configured to protect at least a portion of the display panel, wherein the display panel includes at least one insulating layer disposed at edges of the display panel.

According to various embodiments, a display device may include: a window; a display panel configured to be disposed, at least in part, in a direction facing the window; and a cover panel configured to be disposed in a direction facing the display panel and configured to protect at least a portion of the display panel, wherein the display panel includes: a front substrate; a rear substrate; a sealing member configured to be disposed between the front substrate and the rear substrate so as to seal the front substrate and the rear substrate; a conductive line configured to face the sealing member; a first insulating layer configured to be disposed between the conductive line and the rear substrate; and a second insulating layer configured to be disposed in at least a portion of edges between the sealing member, the conductive line, and the first insulating layer.

According to various embodiments, an electronic device having a display device may include: a window; a touch screen panel configured to be disposed, at least in part, in a direction facing the window; a display panel configured to be disposed in a direction facing the touch screen panel; and a cover panel configured to be disposed in a direction facing the display panel and configured to protect at least a portion of the display panel, wherein the display panel may include: a front substrate; a rear substrate; a sealing member configured to be disposed between the front substrate and the rear substrate so as to seal the front substrate and the rear substrate; a conductive line configured to face the sealing member; a first insulating layer configured to be disposed between the conductive line and the rear substrate; and a second insulating layer configured to be disposed in at least a portion of edges between the sealing member, the conductive line, and the first insulating layer.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a perspective view showing the front side of an electronic device according to various embodiments;

FIG. 2 is a perspective view showing the back side of the electronic device in FIG. 1;

FIG. 3 is an exploded perspective view showing the electronic device in FIG. 1;

FIG. 4A is a cross-sectional view taken along the line A-A′ in FIG. 1, which shows a configuration of a display device according to various embodiments;

FIG. 4B is a cross-sectional view taken along the line A-A′ in FIG. 1, which shows another configuration of a display device according to various embodiments;

FIG. 4C is a cross-sectional view taken along the line A-A′ in FIG. 1, which shows another configuration of a display device according to various embodiments;

FIG. 5 is a plan view showing an embodiment of a second insulating layer in a display device according to various embodiments;

FIG. 6 is a plan view showing another embodiment of a second insulating layer in a display device according to various embodiments; and

FIG. 7 is a cross-sectional view taken along the line A-A′ in FIG. 1, which shows another embodiment of a display device according to various embodiments.

### DETAILED DESCRIPTION

The display device has a TFT layer and an encapsulation layer both ends of which are sealed by a sealing member, and a power supply line of a metal material may be provided between the TFT layer and the encapsulation layer. In this state, when an external impact is applied to the display device, cracks may occur in the sealing member provided between the TFT layer and the encapsulation layer, thereby lowering the adhesion of the sealing member and degrading the sealing. Further, moisture may infiltrate into the TFT layer and the encapsulation layer through the cracks, so that the power supply line of a metal material provided between the TFT layer and the encapsulation layer may be corroded.

Various embodiments provide a display device capable of providing a display panel with high strength by forming at least one insulating layer in the display panel, which prevents cracks from occurring by an external impact, and further provide an electronic device including the same.

According to various embodiments, first and second insulating layers are formed in the display panel in order to prevent the occurrence of cracks due to an external impact, thereby preventing deterioration of adhesion of a sealing member provided in the display panel. In addition, it is possible to prevent moisture from infiltrating into the lines at least on the basis of the occurrence of cracks in the sealing member of the display panel, and to prevent corrosion or deformation of the lines included in the display panel. In addition to provision of a high strength display panel and prevention of corrosion or deformation of the lines as described above, it is possible to improve the waterproof function of the product, to suppressing an increase in the consumption current of the product, and to prevent degradation of image quality of the display device.

An electronic device according to various embodiments disclosed herein may be various types of devices. The electronic device may, for example, include at least one of a portable communication device (e.g., smartphone) a computer device, a portable multimedia device, a portable medical device, a camera, a wearable device, and a home appliance. The electronic device according to one embodiment of the present disclosure is not limited to the above described devices.

The embodiments and the terms used therein are not intended to limit the technology disclosed herein to specific forms, and should be understood to include various modifications, equivalents, and/or alternatives to the corresponding embodiments. In describing the drawings, similar reference numerals may be used to designate similar constituent elements. A singular expression may include a plural expression unless they are definitely different in a context. The terms “A or B”, “one or more of A and/or B”, “A, B, or C”, or “one or more of A, B and/or C” may include all possible combinations of them. The expression “a first”, “a second”, “the first”, or “the second” used in various embodiments of the present disclosure may modify various components regardless of the order and/or the importance but does not limit the corresponding components. When an element (e.g., first element) is referred to as being “(functionally or communicatively) connected,” or “directly coupled” to another element (second element), the element may be connected directly to the another element or connected to the another element through yet another element (e.g., third element).

The term “module” as used herein may include a unit consisting of hardware, software, or firmware, and may, for example, be used interchangeably with the term “logic”, “logical block”, “component”, “circuit”, or the like. The “module” may be an integrated component, or a minimum unit for performing one or more functions or a part thereof. For example, a module may be an Application-Specific Integrated Circuit (ASIC).

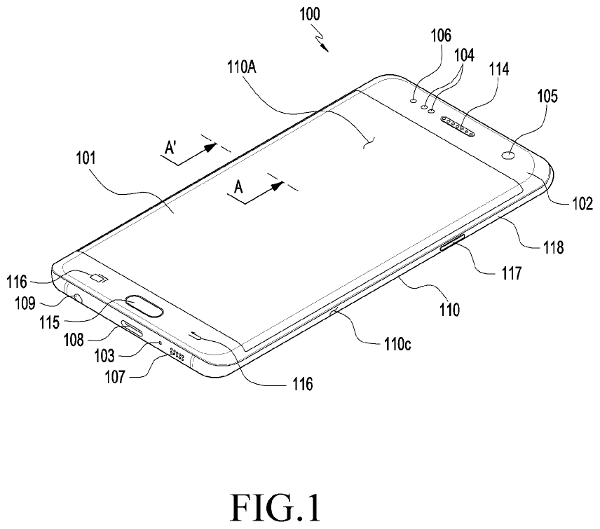

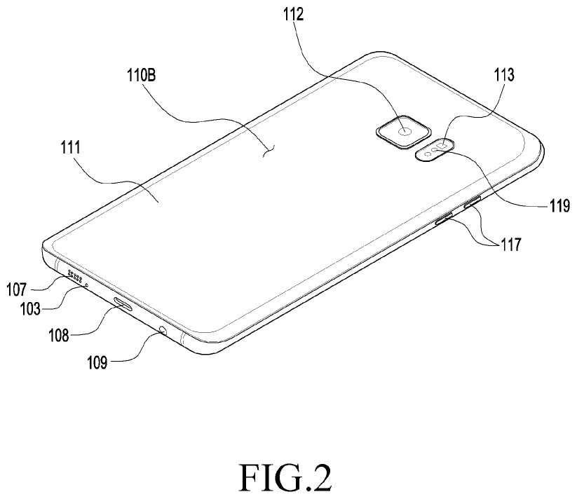

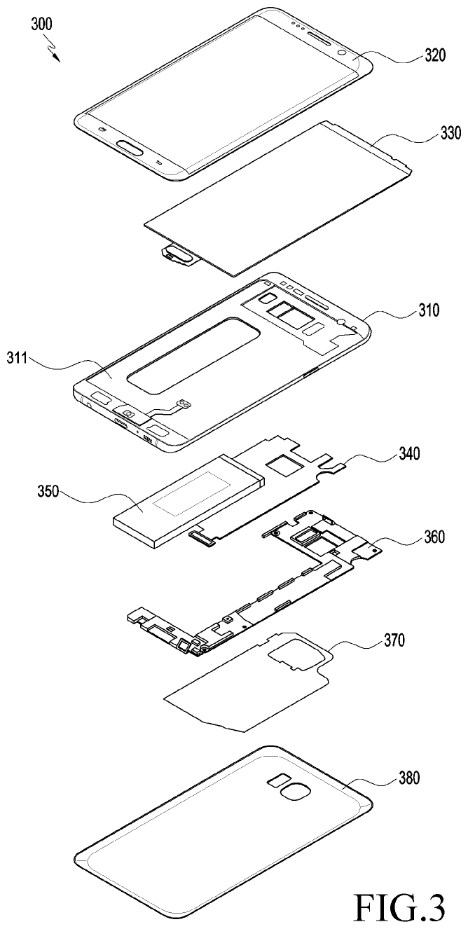

FIG. 1 is a perspective view showing the front side of an electronic device according to various embodiments. FIG. 2 is a perspective view showing the back side of the electronic device in FIG. 1. FIG. 3 is an exploded perspective view showing the electronic device in FIG. 1.

Referring to FIGS. 1 and 2, an electronic device 100 according to an embodiment may include a housing 110 having a first surface (or front surface) 110A, a second surface (or back surface) 110B, and a side surface 110C surrounding a space between the first surface 110A and the second surface 110B. In another embodiment (not shown), the housing may refer to a structure constituting some of the first surface 110A, the second surface 110B, and the side surface 110C in FIG. 1. According to an embodiment, the first surface 110A may be formed by a front plate 102 (e.g., a glass plate or polymer plate including a variety of coating layers) that is, at least in part, substantially transparent. The second surface 110B may be formed by a rear plate 111 that is substantially opaque. The rear plate 111 may be made of, for example, coated or colored glass, ceramic, polymer, metal {e.g., aluminum, stainless steel (STS), or magnesium}, or a combination of two or more of the above materials. The side surface 110C may be formed by a side bezel structure (or “side member”) 118 that is coupled to the front plate 102 and the rear plate 111 and includes metal and/or polymer. In some embodiments, the rear plate 111 and the side bezel structure 118 may be integrally formed, and may include the same material (e.g., a metal material such as aluminum).

According to an embodiment, the electronic device 100 may include at least one of a display 101, audio modules 103, 107, and 114, sensor modules 104 and 119, camera modules 105, 112, and 113, key input devices 115, 116, and 117, an indicator 106, and connector holes 108 and 109. In some embodiments, the electronic device 100 may exclude at least one (e.g., key input devices 115, 116, and 117 or the indicator 106) of the elements, or may further include other elements.

The display 101 may be exposed through, for example, most of the front plate 102. The display 101 may be connected with a touch sensing circuit, a pressure sensor capable of measuring the intensity (pressure) of a touch, and/or a digitizer for detecting a stylus pen by a magnetic field method, or may be disposed adjacent thereto.

The audio modules 103, 107, and 114 may include a microphone hole 103 and speaker holes 107 and 114. A microphone for acquiring external sounds may be disposed inside the microphone hole 103, and in some embodiments, a plurality of microphones may be disposed in order to sense the direction of sound. The speaker holes 107 and 114 may include an external speaker hole 107 and a communication receiver hole 114. In some embodiments, the speaker holes 107 and 114 and the microphone hole 103 may be implemented as a single hole, or a speaker (e.g., a piezo speaker) may be included without the speaker holes 107 and 114.

The sensor modules 104 and, 119 may generate electrical signals or data values corresponding to an internal operating state of the electronic device 100 or corresponding to an external environmental condition. The sensor modules 104 and 119, for example, may include a first sensor module 104 (e.g., a proximity sensor) and/or a second sensor module (not shown) (e.g., a fingerprint sensor), which are disposed on the first surface 110A of the housing 110, and/or a third sensor module 119 (e.g., an HRM sensor) disposed on the second surface 110B of the housing 110. The fingerprint sensor may be disposed on the second surface 110B, as well as on the first surface 110A of the housing 110 (e.g., a home key button 115). The electronic device 100 may further include at least one of sensor modules (not shown) such as a gesture sensor, a gyro sensor, an air pressure sensor, a magnetic sensor, an acceleration sensor, a grip sensor, a color sensor, an infrared (IR) sensor, a biometric sensor, a temperature sensor, a humidity sensor, or an illuminance sensor 104.

The camera modules 105, 112, and 113 may include a first camera device 105 disposed on the first surface 110A of the electronic device 100, a second camera device 112 disposed on the second surface 110B, and/or a flash 113. The camera modules 105 and 112 may include one or more lenses, an image sensor, and/or an image signal processor. The flash 113 may include, for example, a light-emitting diode or a xenon lamp. In some embodiments, two or more lenses (wide angle and telephoto lenses) and image sensors may be disposed on one surface of the electronic device 100.

The key input devices 115, 116, and 117 may include a home key button 115 disposed on the first surface 110A of the housing 110, a touch pad 116 disposed around the home key button 115, and/or a side key button 117 disposed on the side surface 110C of the housing 110. In another embodiment, the electronic device 100 may exclude some or all of the above-mentioned key input devices 115, 116, and 117, and the excluded key input devices 115, 116, and 117 may be implemented in other forms, such as soft keys, on the display 101.

The indicator 106 may be disposed, for example, on the first surface 110A of the housing 110. The indicator 106, for example, may provide status information of the electronic device 100 in the optical form, and may include an LED.

The connector holes 108 and 109 may include a first connector hole 108 capable of receiving a connector (e.g., a USB connector) for transmitting and receiving power and/or data to and from an external electronic device and/or a second connector hole (e.g., an earphone jack) 109 capable of receiving a connector for transmitting and receiving audio signals to and from an external electronic device.

Referring to FIG. 3, the electronic device 300 may include a side bezel structure 310, a first support member 311 (e.g., a bracket), a front plate 320, a display device 330, a printed circuit board 340, a battery 350, a second support member 360 (e.g., a rear case), an antenna 370, and a rear plate 380. In some embodiments, the electronic device 300 may exclude at least one (e.g., the first support member 311 or the second support member 360) of the elements, or may further include other elements. At least one of the elements of the electronic device 300 may be the same as or similar to at least one of the elements of the electronic device 100 in FIG. 1 or 2, and the duplicate description thereof will be omitted hereinafter.

The first support member 311 may be disposed inside the electronic device 300 so as to be connected to the side bezel structure 310, or may be integrally formed with the side bezel structure 310. The first support member 311 may be made of, for example, a metal material and/or a non-metal material (e.g., polymer). The first support member 311 may have a display device 330 coupled to one surface thereof and a printed circuit board 340 coupled to the opposite surface thereof. The printed circuit board 340 may have processors, memories, and/or interfaces mounted thereon. The processors, for example, may include one or more of a central processing unit, an application processor, a graphic processing unit, an image signal processor, a sensor hub processor, or a communication processor.

The memories, for example, may include volatile memories or non-volatile memories.

The interfaces, for example, may include a High Definition Multimedia Interface (HDMI), a Universal Serial Bus (USB) interface, an SD card interface, and/or an audio interface. The interfaces, for example, may electrically or physically connect the electronic device 300 with an external electronic device, and may include a USB connector, an SD card/MMC connector, or an audio connector.

The battery 350 is intended to supply power to at least one element of the electronic device 300, and may include, for example, a non-rechargeable primary battery, a rechargeable secondary battery, or a fuel cell. At least a portion of the battery 350, for example, may be disposed on the plane substantially the same as that of the printed circuit board 340. The battery 350 may be integrally disposed inside the electronic device 100, and may be disposed so as to be detachable from the electronic device 100.

The antenna 370 may be disposed between the rear plate 380 and the battery 350. The antenna 370 may include, for example, a Near Field Communication (NFC) antenna, a wireless charging antenna, and/or a Magnetic Secure Transmission (MST) antenna. The antenna 370, for example, may perform short-range communication with an external device, or may wirelessly transmit and receive power required for charging. In another embodiment, the antenna structure may be made by portions of the side bezel structure 310 and/or the first support member 311 or by a combination thereof.

According to various embodiments, the electronic device 300 can significantly reduce the possibility of breakage of the display device 330 even when the electronic device 300 is subjected to an external impact such as dropping or the like during carrying.

According to an embodiment, when the electronic device 300 drops onto the ground, impact may be transmitted to the upper, lower, left, and right edges, as well as the corners. This impact may cause the breakage of the display device 330 to begin from the portion (e.g., the edges of the display device 330) that is most sensitive to impact. However, according to the embodiment, the breakage rate of the display can be significantly lowered, compared to the prior art, by applying a structure capable of remarkably reducing the possibility of breakage even in the case of an impact to the area corresponding to the edges of the display device 300.

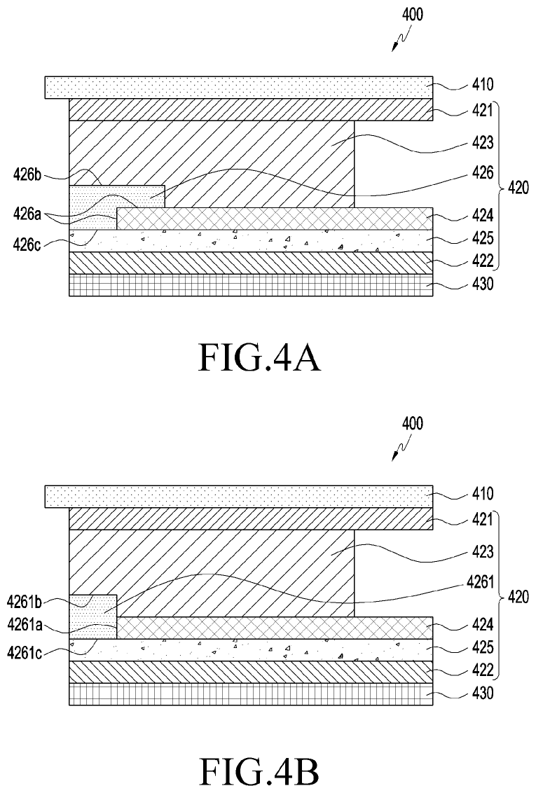

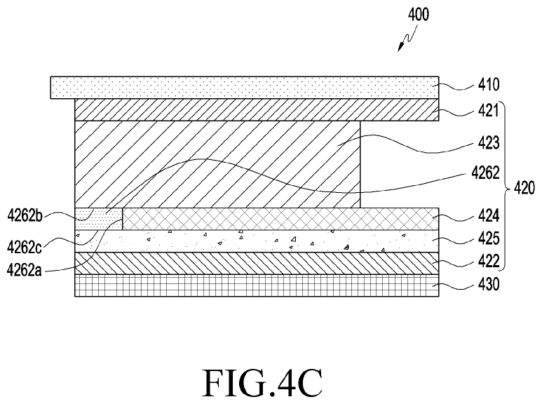

FIG. 4A is a cross-sectional view taken along the line A-A′ in FIG. 1, which shows a configuration of a display device according to various embodiments.

Referring to FIG. 4A, an electronic device (e.g., the electronic device 100 in FIG. 1) may be fixed in such a manner that a display panel 420 is attached to a display mounting surface of a case frame, and a window 410 may be mounted thereon in order to protect the display panel 420.

The display device 400 may include a window 410, a display panel 420, and a cover panel 430.

The display panel 420 may include a touch screen panel (TSP) including a touch sensor in an upper area or an inner area of the display panel 420.

For example, the touch screen panel may be disposed in the upper area of the display panel 420 (e.g., an on-cell type), or may be disposed in the inner area of the display panel 420 (e.g., an in-cell type). Alternatively, a separate touch screen panel may be interposed between the window 410 and the display panel 420.

According to an embodiment, the display panel 420 may include an On-Cell TouchAMOLED)(OCTA) panel. In the present embodiment, the touch screen panel may be disposed on top of the display panel.

The display panel 420 may include at least one of an Organic Light-Emitting Diode (OLED) panel or an On-Cell Touch AMOLED(OCTA) panel. Although an Organic Light-Emitting Diode (OLED) panel will be described as an example in the embodiment, the disclosure is not limited thereto. For example, any panel capable of serving as a display of the electronic device can be applied to the display panel 420.

The cover panel 430 may face the lower surface of the display panel 420 in order to protect the display panel 420.

The display panel 420 may include a front substrate 421, a rear substrate 422, a sealing member 423, a conductive line 424, a first insulating layer 425, and a second insulating layer 426. The front substrate 421 may be disposed on the lower surface of a touch screen panel (not shown).

The rear substrate 422 may be disposed under the front substrate 421 so as to provide a space below the front substrate 421. For example, the sealing member 423, the conductive line 424, the first insulating layer 425, or the second insulating layer 426 may be disposed in the space between the front substrate 421 and the rear substrate 422. The rear substrate 422 may be disposed on the upper surface of the cover panel 430.

The front substrate 421 may include an encapsulation layer, and the rear substrate 422 may include at least one of a TFT layer and a Low-Temperature Polycrystalline Silicon (LTPS) glass.

An organic material may be disposed between the front substrate 421 and the rear substrate 422 of the display panel 420. A sealing member may be applied via at least a portion of the edges of the display panel 420 such that the organic material is sealed without being exposed to the air. For example, the sealing member 423 may be disposed between the front substrate 421 and the rear substrate 422 so as to seal at least a portion of the front substrate 421, the conductive line 424, and the second insulating layer 426.

The conductive line 424 may be attached so as to face the sealing member 423 in order to supply power to a plurality of light-emitting devices (not shown) disposed in the touch screen panel and/or at least a portion of the space between the front substrate 421 and the rear substrate 422. For example, the conductive line 424 may include an ELVDD or ELVSS line for controlling the driving of one or more light-emitting devices including one or more sub light-emitting devices (e.g., R, G, or B). The light-emitting device may include pixels.

The conductive line 424 may be made of a metal material, and the conductive line 424 may include a power supply line or a data signal line. The conductive line 424 will be described as an example of a power supply line or a data signal line, but it is not limited thereto. For example, any line that can be electrically connected may be applied as the conductive line 424. The embodiment will be described by applying a power supply line made of a metal material.

The first insulating layer 425 may be disposed between the conductive line 424 and the rear substrate 422 so as to protect the conductive line 424.

The second insulating layer 426 may be disposed between edges of the sealing member 423, the conductive line 424, and the first insulating layer 425 in order to prevent cracks from occurring due to an external impact in the sealing member 423 of the display panel 420 and in order to block moisture infiltrating into the conductive line 424. For example, the second insulating layer 426 may be disposed so as to cover at least a portion of the end of the conductive line 424.

The first insulating layer 425 or the second insulating layer 426 may include an insulating member. The first insulating layer 425 or the second insulating layer 426 including the insulating member may prevent cracks generated in the display panel 420.

For example, the second insulating layer 426 may prevent cracks from occurring due to an external impact in the display panel 420, thereby preventing the adhesion of the sealing member 423 provided in the display panel 420 from deteriorating, and may prevent moisture from infiltrating into the display panel 420, thereby preventing corrosion or deformation of the power supply line.

The front substrate 421 may include an encapsulation layer (e.g., encapsulation glass), or the rear substrate 422 may include at least one of a TFT layer and a Low-Temperature Polycrystalline Silicon (LTPS) glass. For example, the front substrate 421 or the rear substrate 422 may include a glass material. A light-emitting device may be disposed between the front substrate 421 and the rear substrate 422. A sealing member may be attached to the edges of the front substrate 421 or the rear substrate 422 such that the light-emitting device is hermetically enclosed without being exposed to the air. Since the sealing member 114 is generally made of a glass frit composite, a crack may be generated due to an external impact.

Therefore, at least a part of the outermost portion of the sealing member 423 may be provided with a second insulating layer 426 capable of absorbing an external impact.

As described above in FIG. 4A, the display device 400 according to various embodiments may include a window 410, a display panel 420 disposed to face the lower surface of the window 410, and a cover panel 430 disposed to face the lower surface of the display panel 420. The display panel 420 may include a front substrate 421 and a rear substrate 422 disposed under the window 410 and a sealing member 423 disposed between the front substrate 421 and the rear substrate 422. A conductive line 424 may be disposed on the lower surface of the sealing member 423, and a first insulating layer 425 may be disposed between the conductive line 424 and the rear substrate 422. A second insulating layer 426 may be disposed between the sealing member 423 and the conductive line 424. The second insulating layer 426 may be disposed at the outermost portion of the sealing member 423 and the conductive line 424, and the second insulating layer 426 may be disposed on the upper surface of the outermost portion of the first insulating layer 425.

When an external impact is applied to the display device 400 assembled as described above, the second insulating layer 426 may primarily absorb the external impact, and the first insulating layer 425 may secondarily absorb the same. As described above, the first insulating layer 425 or the second insulating layer 426 may absorb an external impact, thereby preventing cracks from occurring in the sealing member 423, and it is possible to prevent moisture from infiltrating into the display device 400 by protecting the conductive line 424. Therefore, it is possible to prevent corrosion or breakage of the conductive line 424 and to prevent deformation of the conductive line 424. According to an embodiment, the first insulating layer 425 or the second insulating layer 426 may prevent cracks from occurring in the sealing member 423, thereby improving the adhesion of the front substrate 421 and the rear substrate 422. Therefore, the strength of the display device 400 can be enhanced.

According to an embodiment, the first insulating layer 425 or the second insulating layer 426 may prevent moisture from infiltrating into the display device 400, regardless of a crack of the sealing member 423. For example, the first insulating layer 425 or the second insulating layer 426 may prevent moisture from infiltrating into the display device 400, thereby realizing the waterproof function of the display device 400. For example, the first insulating layer 425 or the second insulating layer 426 may be waterproof

According to an embodiment, as described in FIG. 4A, the second insulating layer 426 may have an “L” shape. For example, a first surface 426a of the second insulating layer 426 may cover at least a portion of the outer end of the conductive line 424, a second surface 426b of the second insulating layer 426 may face at least a portion of the sealing member 423, and a third surface 426c of the second insulating layer 426 may face at least a portion of the upper surface of the edge of the first insulating layer 425.

According to an embodiment, FIG. 4B is a cross-sectional view taken along the line A-A′ in FIG. 1, which shows another configuration of a display device according to various embodiments.

Referring to FIG. 4B, a second insulating layer 4261 may have an “I” shape, and the height of the second insulating layer 4261 may be greater than the height of the conductive line 424. For example, the thickness of the second insulating layer 4261 may be greater than the thickness of the conductive line 424. A first surface 4261a of the second insulating layer 4261 may face one surface of the outermost end of the conductive line 424, a second surface 4261b of the second insulating layer 4261 may face at least a portion of the outer end of the sealing member 423, and a third surface 4261c of the second insulating layer 4261 may face at least a portion of the upper surface of the edge of the first insulating layer 425.

According to an embodiment, FIG. 4C is a cross-sectional view taken along the line A-A′ in FIG. 1, which shows another configuration of a display device according to various embodiments.

Referring to FIG. 4C, a second insulating layer 4262 may have a rectangular shape, and the height of the second insulating layer 4262 may be equal to the height of the conductive line 424. For example, the thickness of the second insulating layer 4262 may be equal to the thickness of the conductive line. A first surface 4262a of the second insulating layer 4262 may face one surface of the outermost end of the conductive line 424, a second surface 4262b of the second insulating layer 4262 may face at least a portion of the lower surface of the sealing member 423, and a third surface 4262c of the second insulating layer 4262 may face at least a portion of the upper surface of the edge of the first insulating layer 425.

As described above, the second insulating layer may have at least one of an “L” shape, an “I” shape, or a rectangular shape. However, the second insulating layer is not limited thereto, and may have any shape other than the “L” shape, the “I” shape, or the rectangular shape.

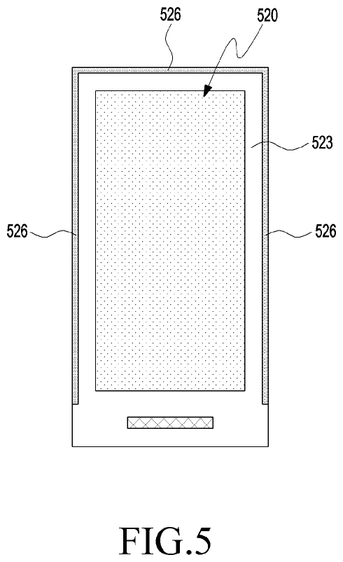

FIG. 5 is a plan view showing an embodiment of a second insulating layer 526 in a display device according to various embodiments.

Referring to FIG. 5, the second insulating layer 526 may be disposed along the edges of the display panel 520. For example, the second insulating layer 526 may be disposed on at least one of the upper surface, the left surface, and the right surface of the edges of the display panel 520 (for example, may be disposed on the upper surface, the left surface, and the right surface, respectively).

The second insulating layer 526 may be disposed on the three outermost surfaces of the display panel 520 so as to absorb an external impact, thereby preventing cracks from occurring in the sealing member 523.

The lower surface of the display panel 520 is provided with a frame and a bracket of an electronic device (e.g., the electronic device 100 in FIG. 1), thereby absorbing an external impact to prevent cracks from occurring in the sealing member 523. Therefore, the second insulating layer may not be further disposed on the lower surface of the display panel 520. Thus, it is possible to reduce the manufacturing cost of the second insulating layer.

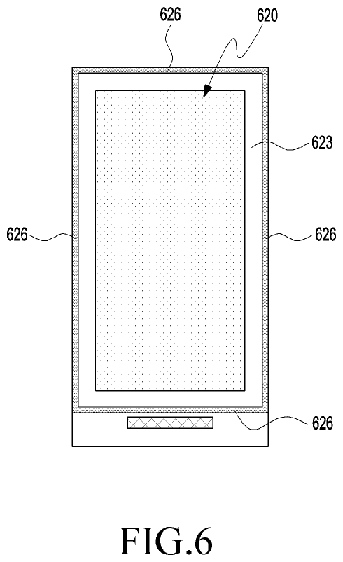

FIG. 6 is a plan view showing another embodiment of a second insulating layer 626 that is in a display device according to various embodiments.

Referring to FIG. 6, the second insulating layer 626 may be disposed along the entire edges of the display panel 620. For example, the second insulating layer 626 may be disposed on at least three of the upper surface, the lower surface, the left surface, or the right surface of the edges of the display panel 620 (for example, may be disposed on the upper surface, the lower surface, the left surface, and the right surface, respectively).

The second insulating layer 626 may be disposed on the four outermost surfaces of the display panel 620 so as to absorb an external impact, thereby preventing cracks from occurring in the sealing member 623. The second insulating layer 626 may be disposed to cover the entire surfaces of the edges of the display panel 620. Therefore, the strength of the display panel 620 may be further improved.

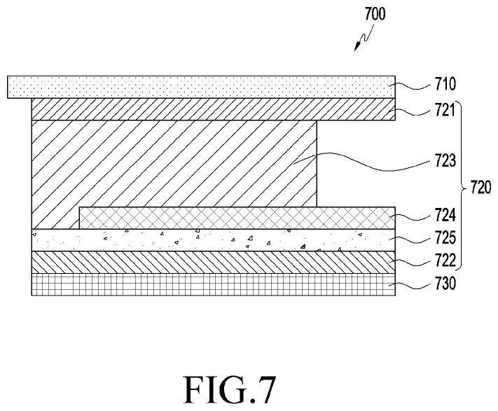

FIG. 7 shows a display device 700 according to various embodiments.

Referring to FIG. 7, the display device 700 may include a window 710, a display panel 720, and a cover panel 730. The display panel 720 may include a front substrate 721, a rear substrate 722, a sealing member 723, a conductive line 724, and an insulating layer 725.

The front substrate 721 may be disposed on the lower surface of the window 710 so as to be attached to the rear substrate 722 by means of a sealing member 723, which will be described later.

The rear substrate 722 may be disposed on the upper surface of the cover panel 730 so as to be attached to the front substrate 721 by means of the sealing member 723.

The conductive line 724 may be attached to the sealing member 723 to face the same in order to supply power to a plurality of light-emitting devices (not shown) provided in a touch screen panel (not shown), the front substrate 721, and the rear substrate 722.

The insulating layer 725 may be disposed on the lower surface of the conductive line 724 so as to protect the conductive line 724, so as to prevent cracks from occurring in the display panel 720 due to an external impact, and so as to block moisture infiltrating into the conductive line 724. The insulating layer 725 may face at least a portion of the edges of the sealing member 723.

According to an embodiment, the display panel 720 may include a front substrate 721 and a rear substrate 722 disposed under the window 710, and a sealing member 723 may be provided between the front substrate 721 and the rear substrate 722 so as to seal the front substrate 721 and the rear substrate 722. A conductive line 724 may be disposed on the lower surface of the sealing member 723, and one insulating layer 725 may be disposed between the conductive line 724 and the rear substrate 722.

According to an embodiment, an insulating layer (i.e., a dam) 725 may be formed in the display panel 720 to prevent cracks from occurring in the sealing member due to an external impact, thereby preventing the breakage of the sealing member provided in the display panel 720 or the deterioration of the adhesion thereof. Further, it is possible to prevent corrosion or deformation of the line by preventing moisture from infiltrating into the display panel.

According to various embodiments, a display device may include: a window; a display panel configured to be disposed, at least in part, in a direction facing the window; and a cover panel configured to be disposed in a direction facing the display panel and configured to protect at least a portion of the display panel, wherein the display panel includes at least one insulating layer disposed at edges of the display panel.

According to various embodiments, the at least one insulating layer may include a first insulating layer and a second insulating layer, wherein the first insulating layer may be disposed between a conductive line included in the display panel and a rear substrate included in the display panel, and wherein the second insulating layer may be located in at least a portion of edges of a sealing member disposed between a front substrate and the rear substrate of the display panel, and the second insulating layer may be disposed in at least a portion of edges between the conductive line and the first insulating layer.

According to various embodiments, the at least one insulating layer may be made of an insulating member.

According to various embodiments, the first insulating layer or the second insulating layer may be configured to prevent, at least in part, moisture from infiltrating into the conductive line.

According to various embodiments, a display device may include: a window; a display panel configured to be disposed, at least in part, in a direction facing the window; and a cover panel configured to be disposed in a direction facing the display panel and configured to protect at least a portion of the display panel, wherein the display panel may include: a front substrate; a rear substrate; a sealing member configured to be disposed between the front substrate and the rear substrate so as to seal the front substrate and the rear substrate; a conductive line configured to face the sealing member; a first insulating layer configured to be disposed between the conductive line and the rear substrate; and a second insulating layer configured to be disposed in at least a portion of edges between the sealing member, the conductive line, and the first insulating layer.

According to various embodiments, the display panel may include an On-Cell Touch AMOLED (OCTA) panel.

According to various embodiments, the front substrate may include an encapsulation layer, and the rear substrate may include at least one of a TFT layer or a Low-Temperature Polycrystalline Silicon (LTPS) glass.

According to various embodiments, the second insulating layer may be disposed on at least one of an upper surface, a left surface, or a right surface of edges of the display panel.

According to various embodiments, the second insulating layer may be disposed on at least three of an upper surface, a lower surface, a left surface, or a right surface of edges of the display panel.

According to various embodiments, the first insulating layer or the second insulating layer may include an insulating member.

According to various embodiments, the display device may further include a touch screen panel.

According to various embodiments, the conductive line may be made of a metal material, and may include at least one of a power supply line and a data signal line.

According to various embodiments, the display panel may include: a front substrate; a rear substrate; a sealing member configured to be disposed between the front substrate and the rear substrate so as to seal the front substrate and the rear substrate; a conductive line configured to face the sealing member; and an insulating layer configured to be disposed between the conductive line and the rear substrate.

According to various embodiments, an electronic device including a display device may include: a window; a touch screen panel configured to be disposed, at least in part, in a direction facing the window; a display panel configured to be disposed in a direction facing the touch screen panel; and a cover panel configured to be disposed in a direction facing the display panel and configured to protect at least a portion of the display panel, wherein the display panel may include: a front substrate; a rear substrate; a sealing member configured to be disposed between the front substrate and the rear substrate so as to seal the front substrate and the rear substrate; a conductive line configured to face the sealing member; a first insulating layer configured to be disposed between the conductive line and the rear substrate; and a second insulating layer configured to be disposed in at least a portion of edges between the sealing member, the conductive line, and the first insulating layer.

According to various embodiments, the first insulating layer or the second insulating layer may be configured to prevent, at least in part, moisture from infiltrating into the conductive line.

According to various embodiments, the display panel may include an On-Cell Touch AMOLED (OCTA) panel.

While the present disclosure has been shown and described with reference to certain embodiments thereof, it will be understood by those skilled in the art that various changes in form and details may be made therein without departing from the spirit and scope of the present disclosure as defined by the appended claims.

1. A display device comprising:
a window;
a display panel configured to be disposed, at least in part, in a direction facing the window; and
a cover panel configured to be disposed in a direction facing the display panel and configured to protect at least a portion of the display panel,
wherein the display panel comprises at least one insulating layer disposed at edges of the display panel.

2. The display device of claim 1, wherein the at least one insulating layer comprises a first insulating layer and a second insulating layer,
wherein the first insulating layer is disposed between a conductive line included in the display panel and a rear substrate included in the display panel, and
wherein the second insulating layer is located in at least a portion of edges of a sealing member disposed between a front substrate and the rear substrate of the display panel, and the second insulating layer is disposed in at least a portion of edges between the conductive line and the first insulating layer.

3. The display device of claim 2, wherein the first insulating layer or the second insulating layer is configured to prevent, at least in part, moisture from infiltrating into the conductive line.

4. The display device of claim 1, wherein the at least one insulating layer comprises an insulating member.

5. A display device comprising:
a window;
a display panel configured to be disposed, at least in part, in a direction facing the window; and
a cover panel configured to be disposed in a direction facing the display panel and configured to protect at least a portion of the display panel,
wherein the display panel comprises:
a front substrate;
a rear substrate;
a sealing member configured to be disposed between the front substrate and the rear substrate so as to seal the front substrate and the rear substrate;
a conductive line configured to face the sealing member;
a first insulating layer configured to be disposed between the conductive line and the rear substrate; and
a second insulating layer configured to be disposed in at least a portion of edges between the sealing member, the conductive line, and the first insulating layer.

6. The display device of claim 5, wherein the display panel comprises an On-Cell Touch AMOLED (OCTA) panel.

7. The display device of claim 5, wherein the front substrate comprises an encapsulation layer, and
wherein the rear substrate comprises at least one of a TFT layer or a Low-Temperature Polycrystalline Silicon (LTPS) glass.

8. The display device of claim 5, wherein a cross-section of the second insulating layer has an “L” shape, an “I” shape, or a rectangular shape.

9. The display device of claim 5, wherein the second insulating layer is disposed on at least one of an upper surface, a left surface, or a right surface of edges of the display panel.

10. The display device of claim 5, wherein the second insulating layer is disposed on at least three of an upper surface, a lower surface, a left surface, or a right surface of edges of the display panel.

11. The display device of claim 5, wherein the first insulating layer or the second insulating layer comprises an insulating member.

12. The display device of claim 5, wherein the display device further comprises a touch screen panel.

13. The display device of claim 5, wherein the conductive line comprises at least one of a power supply line and a data signal line.

14. The display device of claim 5, wherein the display panel comprises:
a front substrate;
a rear substrate;
a sealing member configured to be disposed between the front substrate and the rear substrate so as to seal the front substrate and the rear substrate;
a conductive line configured to face the sealing member; and
an insulating layer configured to be disposed between the conductive line and the rear substrate.

15. An electronic device comprising a display device, the electronic device comprising:
a window;
a touch screen panel configured to be disposed, at least in part, in a direction facing the window;
a display panel configured to be disposed in a direction facing the touch screen panel; and
a cover panel configured to be disposed in a direction facing the display panel and configured to protect at least a portion of the display panel,
wherein the display panel comprises:
a front substrate;
a rear substrate;
a sealing member configured to be disposed between the front substrate and the rear substrate so as to seal the front substrate and the rear substrate;
a conductive line configured to face the sealing member;
a first insulating layer configured to be disposed between the conductive line and the rear substrate; and
a second insulating layer configured to be disposed in at least a portion of edges between the sealing member, the conductive line, and the first insulating layer.
